(19) United States
(12) Patent Application Publication
(10) Pub. No.: US 2012/0085383 A1
(43) Pub. Date: Apr. 12, 2012

(54) SOLAR CELL MODULE AND METHOD OF MANUFACTURING THE SAME

(75) Inventors: Young-Sang Cho, Yongin-si (KR); So-Young Lim, Hwaseong-si (KR); Tae-Hong Min, Gumi-si (KR); Ki-Won Choi, Suwon-si (KR)

(73) Assignee: SAMSUNG ELECTRONICS CO., LTD., Suwon-si (KR)

(21) Appl. No.: 13/159,663

(22) Filed: Jun. 14, 2011

(30) Foreign Application Priority Data
Oct. 11, 2010 (KR) 10-2010-0098908

(51) Int. Cl. H01L 31/05

(52) U.S. Cl. 136/244

(57) ABSTRACT

A solar cell module having a reduced thickness using a flip-chip approach includes a transparent substrate, a transparent electrode interconnection disposed on the transparent substrate, and a plurality of solar cells disposed on the transparent electrode interconnection, each solar cell having at least one protrusion formed on one surface of the solar cell, the protrusion being bonded to the transparent electrode interconnection.

### CROSS-REFERENCE TO RELATED APPLICATION

This application claims priority from Korean Patent Application No. 10-2010-0098908 filed on Oct. 11, 2010 in the Korean Intellectual Property Office, and all the benefits accruing therefrom, under 35 U.S.C. 119, the contents of which in its entirety are herein incorporated by reference.

### BACKGROUND

1. Field of the Invention

The present inventive concept relates to a solar cell module, and more particularly, to a solar cell module that uses a flip-chip approach and has a reduced thickness.

2. Description of the Related Art

A solar cell is a device which converts energy of light into electrical energy. In a solar cell, light that is incident on a semiconductor material creates an electron-hole pair (EHP) within the semiconductor material. An electric field produced at a pn junction causes electrons to move to an n-type semiconductor and holes to move to a p-type semiconductor, thereby generating electrical current and, therefore, power. An assembly of multiple solar cells is commonly referred to as a solar module. Solar modules are commonly used to capture light energy from sunlight and to convert the captured light energy to electrical energy. Solar modules are commonly referred to as solar panels.

Recently, research has been conducted on a compact, thin, lightweight, and high power solar cell module that can be used as an auxiliary power supply for portable information devices such as mobile phones or personal digital assistants (PDAs).

### SUMMARY

The present inventive concept provides a solar cell module having a reduced thickness, which can be manufactured using a connection approach that does not include wire bonding.

The present inventive concept also provides a solar cell module having a reduced thickness by eliminating a printed circuit board (PCB) substrate.

These and other features of the present inventive concept will be described in or be apparent from the following description of the preferred embodiments.

According to an aspect of the present inventive concept, there is provided a solar cell module including a transparent substrate, a transparent electrode interconnection disposed on the transparent substrate, and a plurality of solar cells disposed on the transparent electrode interconnection. Each solar cell has at least one protrusion formed on one surface of the solar cell, the protrusion being bonded to the transparent electrode interconnection.

In some exemplary embodiments, the transparent substrate comprises glass.

In some exemplary embodiments, the transparent electrode interconnection comprises at least one material selected from the group consisting of Indium Tin Oxide (ITO), Indium Zinc Oxide (IZO), Carbon Nanotube (CNT), nanowire, and conductive polymer.

In some exemplary embodiments, recesses are formed at locations on the transparent electrode interconnection in correspondence with locations of the protrusions.

In some exemplary embodiments, an anisotropic conductive film (ACF) is interposed between the transparent electrode interconnection and the protrusion.

In some exemplary embodiments, the module further comprises a transparent resin surrounding the plurality of solar cells. In some exemplary embodiments, the transparent resin comprises at least one of underfill resin and ethylene vinyl acetate (EVA).

In some exemplary embodiments, the plurality of solar cells are electrically connected by the transparent electrode interconnection. In some exemplary embodiments, two ends of the transparent electrode interconnection act as first and second electrodes that allow contact with an exterior of the module, and the first and second electrodes are disposed adjacent to one edge of the transparent substrate.

According to another aspect of the present inventive concept, there is provided a solar cell module, comprising: a transparent substrate; a transparent electrode interconnection disposed on the transparent substrate; and a plurality of solar cells disposed on the transparent electrode interconnection, each solar cell having at least one protrusion formed on one surface of the solar cell, the protrusion being bonded to the transparent electrode interconnection. Recesses are formed at locations on the transparent electrode interconnection corresponding to locations of the protrusions, the recesses mating with the protrusions.

In some exemplary embodiments, the transparent substrate comprises glass.

In some exemplary embodiments, the transparent electrode interconnection comprises at least one material selected from the group consisting of Indium Tin Oxide (ITO), Indium Zinc Oxide (IZO), Carbon Nanotube (CNT), nanowire, and conductive polymer.

In some exemplary embodiments, an anisotropic conductive film (ACF) is interposed between the transparent electrode interconnection and the protrusion.

In some exemplary embodiments, the module further comprises a transparent resin surrounding the plurality of solar cells.

In some exemplary embodiments, the transparent resin comprises at least one of underfill resin and ethylene vinyl acetate (EVA).

In some exemplary embodiments, the plurality of solar cells are electrically connected by the transparent electrode interconnection.

In some exemplary embodiments, two ends of the transparent electrode interconnection act as first and second electrodes that allow contact with an exterior of the module, and the first and second electrodes are disposed adjacent to one edge of the transparent substrate.

According to another aspect of the present inventive concept, there is provided an energy conversion module, comprising: a transparent substrate; a transparent electrode interconnection disposed on the transparent substrate; and a plurality of energy conversion cells disposed on the transparent electrode interconnection, each energy conversion cell having at least one protrusion formed on one surface of the energy conversion cell, the protrusion being bonded to the transparent electrode interconnection.

In some exemplary embodiments, the energy conversion cells are solar cells converting light energy into electrical energy.

In some exemplary embodiments, the energy conversion module is a solar cell module.

According to another aspect of the present inventive concept, there is provided a method of manufacturing a solar cell module, the method including disposing a transparent electrode interconnection on a transparent substrate; providing a plurality of solar cells, each having at least one protrusion formed on one surface thereof; interposing an anisotropic conductive film (ACF) between the transparent electrode interconnection and the protrusion; thermally compressing the solar cells having the protrusion thereon against the transparent electrode interconnection; and bonding the protrusion to the transparent electrode interconnection using a partially melted and solidified ACF so that they conduct to each other.

### BRIEF DESCRIPTION OF THE DRAWINGS

The foregoing and other features and advantages of the inventive concept will be apparent from the detailed description of preferred embodiments of the inventive concept contained herein, as illustrated in the accompanying drawings, in which like reference characters refer to the same parts or elements throughout the different views. The drawings are not necessarily to scale, emphasis instead being placed upon illustrating the principles of the inventive concept. In the drawings, the thickness of layers and regions may be exaggerated for clarity.

FIG. 1 is a schematic cross-sectional view of a conventional solar cell module.

FIG. 2 is a schematic cross-sectional view of a solar cell module according to an embodiment of the present inventive concept.

FIG. 3A is a schematic rear view of the solar cell module of FIG. 2.

FIG. 3B is a schematic plan view of the solar cell module of FIG. 2.

FIG. 4A is a schematic view which illustrates a solar cell module having a reduced number of vertical interconnections compared to the solar cell shown in FIG. 3A.

FIG. 4B is a schematic view which illustrates a solar cell module having a smaller number of vertical interconnections than those shown in FIG. 3B.

FIG. 5 is a flowchart of a method of manufacturing a solar cell module according to an embodiment of the present inventive concept.

FIGS. 6 through 9 are schematic cross-sectional views sequentially illustrating steps of a method of manufacturing a solar cell module according to an embodiment of the present inventive concept.

FIGS. 10A and 10B are schematic cross-sectional views of a solar cell module according to another embodiment of the present inventive concept.

FIG. 11 is a flowchart of a method of manufacturing a solar cell module according to another embodiment of the present inventive concept.

### DETAILED DESCRIPTION

The present inventive concept will be described in detail hereinafter with reference to the accompanying drawings, in which preferred embodiments of the inventive concept are shown. This inventive concept may, however, be embodied in different forms and should not be construed as limited to the embodiments set forth herein. Rather, these embodiments are provided so that this description will be thorough and complete, and will fully convey the scope of the inventive concept to those skilled in the art.

It will also be understood that when a layer is referred to as being “on” another layer or substrate, it can be directly on the other layer or substrate, or intervening layers may also be present. In contrast, when an element is referred to as being “directly on” another element, there are no intervening elements present.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The use of the terms “a” and “an” and “the” and similar references in the context of describing the inventive concept (especially in the context of the claims) are to be construed to cover both the singular and the plural, unless otherwise indicated herein or clearly contradicted by context. The terms “comprising,” “having,” “including,” and “containing” are to be construed as open-ended terms, i.e., meaning “including, but not limited to,” unless otherwise noted.

Unless defined otherwise, all technical and scientific terms used herein have the same meaning as commonly understood by one of ordinary skill in the art to which this inventive concept belongs. It is noted that the use of any and all examples, or exemplary terms provided herein is intended merely to better describe the inventive concept and is not a limitation on the scope of the inventive concept unless otherwise specified.

The present inventive concept will be described with reference to perspective views, cross-sectional views, and/or plan views in the figures, in which preferred embodiments of the inventive concept are shown. Thus, the profile of an exemplary view may be modified according to manufacturing techniques and/or allowances. That is, the embodiments of the inventive concept are not intended to limit the scope of the present inventive concept but cover all changes and modifications that can be caused due to a change in manufacturing process. Thus, regions shown in the drawings are illustrated in schematic form and the shapes of the regions are presented simply by way of illustration and not as a limitation.

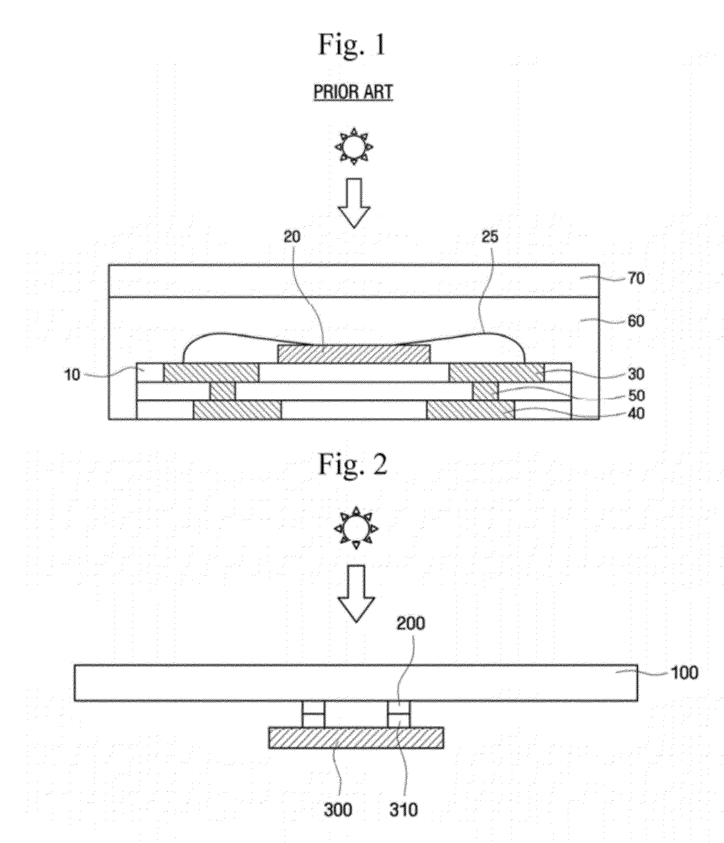

FIG. 1 is a schematic cross-sectional view of a conventional solar cell module. Referring to FIG. 1, a general solar cell module includes a plurality of solar cells 20 disposed on a printed circuit board (PCB) substrate 10, a transparent resin 60 covering and protecting the solar cells 20, and a glass panel 70 that is bonded onto the transparent resin 60 and protects the inside of the solar cell module against external shock.

During operation, light is incident on the solar cell 20. A resulting electric current flows to the PCB substrate 10 through a wire 25 that connects the solar cell 20 to the PCB substrate 10. The PCB substrate 10 can include a first metal layer 30, a conductive via hole 50 and a second metal layer 40, which are sequentially stacked. The electric current flowing through the wire 25 flows out of the solar cell module for external use through an external contact terminal that is formed with opposite polarities on the second metal layer 40, which is exposed to the outside environment. The wire 25 connects the solar cell 20 to the PCB substrate 10 and may be made of a highly conductive material, such as, copper or gold, which facilitates the movement of electrons and holes.

Wire bonding of the solar cell 20 to the PCB substrate 1 requires a space equal to an area occupied by the wire 25. Specifically, when the solar cell 20 is connected to the PCB substrate 10 via the wire 25, the wire 25 projects upwards from the solar cell 20. As a result, the wire 25 has to be sufficiently thick to resist erosion against the transparent resin 60. This creates a limitation on how thin the solar cell module can be. That is, with this conventional configuration, it is difficult to achieve a lightweight, ultra-thin solar cell module.

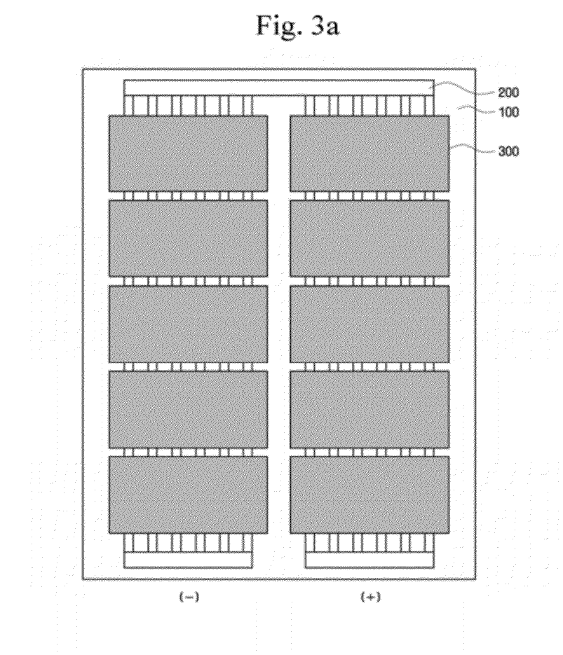

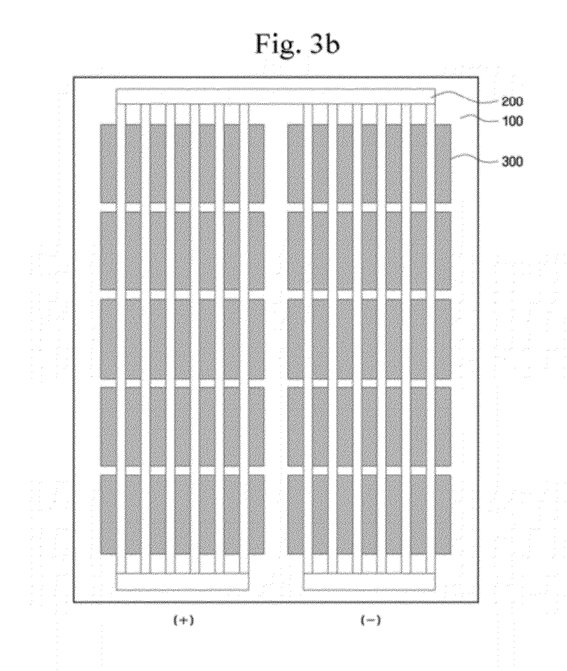

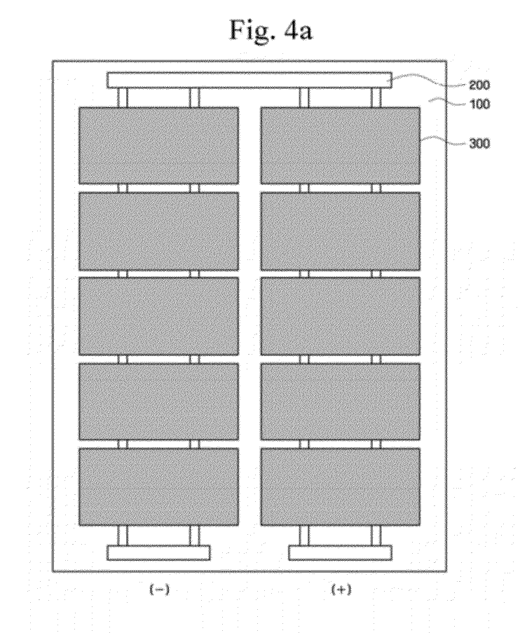

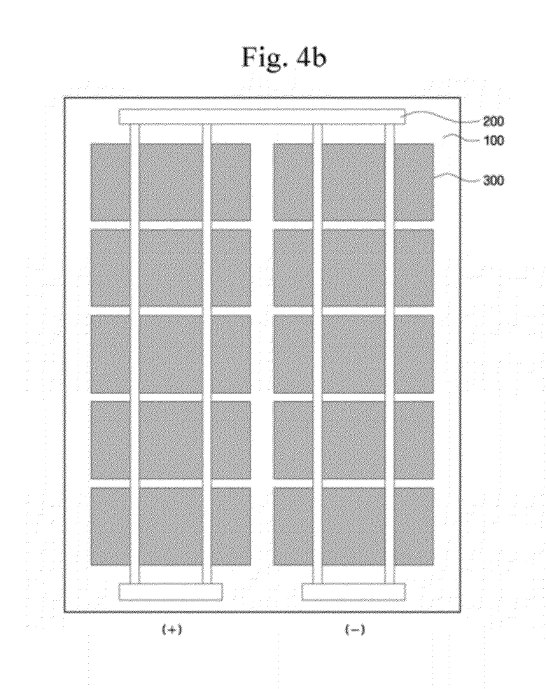

Hereinafter, a solar cell module according to an embodiment the present inventive concept will be described in detail with reference to FIGS. 2, 3A, 3B, 4A and 4B. FIG. 2 is a schematic cross-sectional view of a solar cell module according to an embodiment of the present inventive concept, FIGS. 3A and 3B are a schematic rear view and a schematic plan view, respectively, of the solar cell module of FIG. 2. FIGS. 4A and 4B illustrate a solar cell module having a reduced number of vertical interconnections compared to the solar cell module shown in FIGS. 3A and 3B.

Referring to FIG. 2, the solar cell module according to the present exemplary embodiment can include a transparent substrate 100, a transparent electrode interconnection 200 formed on the transparent substrate 100, and a plurality of solar cells 300. According to some exemplary embodiments, each solar cell 300 includes protrusions 310 formed on one surface of the solar cell. The protrusions are bonded to respective transparent electrode interconnections 200.

In some exemplary embodiments, the transparent substrate 100 is made of a transparent material that permits light to pass through the transparent substrate 100. The transparent material of the transparent substrate 100 may be, for example, glass, transparent plastic film, or transparent plastic sheet, or an opaque material suitable for the application.

More specifically, in some exemplary embodiments, the transparent plastic film may include, for example, a polycarbonate-based material, a polysulfone-based material, a polyacrylate-based material, a polystyrene-based material, a polyvinyl chloride (PVC)-based material, a polyvinyl alcohol (PVA)-based material, a polynorbornene-based material, or a polyester-based material.

According to the exemplary embodiments, specific examples of the transparent substrate 100 may include polyethylene terephtalate or polyethylene naphthalate. Alternatively, according to some exemplary embodiments, the transparent substrate 100 may be made of a transparent flexible material suitable for flexible electronic devices such as, for example, a polycarbonate-based material, a polyethersulfone-based material, or a polyarylate-based material.

In some solar cell modules, a transparent panel is disposed on a transparent resin that is filled to protect a solar cell, a printed circuit board (PCB) substrate, and a wire connecting the solar cell to the PCB substrate. That is, since the transparent resin may not by itself be rigid enough to protect the internal components against external shock, some solar cell modules further include the transparent panel that is disposed on the cured transparent resin and protects the structure against external shock.

In contrast to these other solar cell modules, according to the exemplary embodiments of the inventive concept, the transparent substrate 100 serves to protect the underlying solar cell 300 while providing for the attachment of the solar cell 300 directly to the transparent electrode interconnection 200 without the need for wire bonding. Thus, the transparent substrate 100 according to the exemplary embodiments of the inventive concept may be formed of, for example, glass having high hardness or tempered glass so as to support and protect the solar cell 300 and the transparent electrode interconnection 200.

According to some exemplary embodiments, the transparent electrode interconnection 200 is disposed between the underlying transparent substrate 100 and the solar cell 300. The transparent electrode interconnection 200 may be formed of a transparent material that allows light to pass through the transparent electrode interconnection 200. More specifically, as shown in FIG. 2, in some exemplary embodiments, a top surface of the transparent substrate 100 is irradiated with sunlight. Thus, if the transparent electrode interconnection 200 were to be formed of an opaque metal material such as copper (Cu), aluminum (Al) or silver (Ag) such that it covered a front surface of the transparent substrate 100, an amount of sunlight corresponding to the area of the electrode interconnection 200 will not be absorbed, thus resulting in shading loss.

In some exemplary embodiments, the transparent electrode interconnection 200 may be formed of for example, at least one material selected from the group consisting of indium tin oxide (ITO), indium zinc oxide (IZO), carbon nanotube (CNT), nanowire, and conductive polymer. Since these materials have low resistance while retaining excellent conductivity and optical transmittance (more than 85%), the transparent electrode interconnection 200 formed of these materials may be electrically connected to the solar cells 300 such that they carry electrons and holes and deliver and supply power for external connection and use.

In particular, since CNTs, nanowires, and conductive polymers are more flexible than ITO and IZO, in some particular exemplary embodiments, the transparent electrode interconnection 200 may be formed of CNT, nanowire, or conductive polymer when the solar cell module according to the present embodiment is used in flexible electronic devices. In this case, any type of CNTs may be used. For example, in some exemplary embodiments, the transparent electrode interconnection 200 may be fanned of a mixture of at least one of different types of CNTs including single-walled CNT (SWCNT), double-walled CNT (DWCNT), and multi-walled CNT (MWCNT).

Alternatively, n some exemplary embodiments, the transparent electrode interconnection 200 may be made of a mixture of at least one of transparent conductive materials such as ITO, IZO, CNT, nanowire, and conducting polymer. That is, in some exemplary embodiments, formation of the transparent electrode interconnection 200 includes mixing at least one of these transparent conductive materials into an organic solvent and/or water and adding a dispersing agent or photocurable material thereto to produce a transparent conductive composition, applying the transparent conductive composition on the transparent substrate 100 and forming a coating thereon, and patterning the coating into a desired shape.

In these exemplary embodiments, any common organic solvent may be used. For example, alcohols, ketones, glycols, glycol ethers, glycol ether acetates, acetates, terpineol, or a mixture of at least one of these organic solvents may be used as the organic solvent.

Also, in these exemplary embodiments, any normal dispersing agent may be used. For example, the dispersing agent may be sodium dodecyl sulfate (SDS), triton X, Tween20 (polyoxyethyelene sorbitan monooleate), or cetyl trimethyl ammonium bromide (CTAB).

In some exemplary embodiments, in order to form the transparent electrode interconnection 200, the composition may be applied to the transparent substrate 100 using a common coating technique such as spin coating, spray coating, filtration, or bar coating. One of these techniques may be selected appropriately depending on the characteristics of solution and the desired application. In this case, the transparent substrate 100 may be subjected to surface treatment prior to the application of the composition using any known surface treatment method such as oxygen (O₂) plasma treatment.

As noted above, light incident on the solar cell 300 creates an electron-hole pair (EHP) within a semiconductor material. An electric field produced at a pn junction causes electrons to move to an N-type semiconductor and holes to move to a P-type semiconductor, thereby generating electrical current and power.

That is, the solar cell 300 includes the semiconductor material that absorbs incident sunlight to generate electric charges and first and second electrodes disposed on a light-receiving surface of the semiconductor material. Depending on application, the first and second electrodes may be located on opposite surfaces.

In general, it is difficult to obtain high efficiency in a single solar cell that has a comparatively large area, that is, an area larger than a predetermined desirable area. In order to increase the electrical power of a solar cell module, a plurality of solar cells may be typically connected using a connecting electrode. Alternatively, a grid electrode may be inserted into a unit cell so as to efficiently collect electrons. In particular, in some solar cell modules, a plurality of solar cells may be connected by wire bonding. As described above, since a wire occupies a predetermined space, in some cases, the wire bonding may make it difficult to achieve a solar cell module having a reduced thickness.

To overcome this, in the solar cell module according to the present exemplary embodiments of the inventive concept, the solar cell 300 is formed with protrusions 310 formed on one surface of the solar cell 300. The protrusions 310 electrically conduct with first and second electrodes in the solar cell 300 and are bonded to the transparent electrode interconnection 200 such that the solar cell 300 is fixed onto the transparent substrate 100. In some particular exemplary embodiments, recesses are formed at locations on the transparent electrode interconnection 200 corresponding to locations of the protrusions 310. The recesses mate with the protrusions 310. Thus, the protrusions 310 on the solar cell 300 adhere to the recesses in the transparent electrode interconnection 200, thereby achieving flip-chip bonding.

More specifically, in some exemplary embodiments, an anisotropic conductive film (ACF) may be interposed between the recesses in the transparent electrode interconnection 200 and the protrusions 310 on the solar cell 300. In some exemplary embodiments, the ACF may be formed by dispersing conductive particles in a thermo-setting resin. That is, the ACF may be interposed between the recesses and the protrusions 310 and thermally compressed to melt the ACF. Next, the ACF is cooled for solidification, thereby achieving adhesion between the recesses and the protrusions 310. Since conductive particles are dispersed within the ACF, electrical conduction may be provided between the recesses and protrusions 310.

As described above, in contrast to some solar cell modules that include a plurality of solar cells connected by wire bonding, the solar cell module according to the present exemplary embodiments of the inventive concept includes a plurality of solar cells 300 electrically connected to each other without a separate wire. As described in detail above, this can be achieved by forming the transparent electrode interconnection 200 on the transparent substrate 100 and arranging the plurality of solar cells 300 on the transparent electrode interconnection 200. Thus, the solar cell module according to the present exemplary embodiments is thinner and more lightweight than other solar cell modules.

FIG. 3A is a schematic rear view of the solar cell module of FIG. 2, and FIG. 3B is a schematic plan view of the solar cell module of FIG. 2. FIGS. 3A and 3B schematically illustrate a pattern of the transparent electrode interconnection 200 and arrangement of the solar cell module 300, according to exemplary embodiments of the inventive concept. As described above, referring to FIGS. 3A and 3B, the solar cell module according to the present exemplary embodiments includes the transparent substrate 100 and the transparent electrode interconnection 200 formed on the transparent substrate 100. According to the inventive concept, the transparent electrode interconnection 200 may have different patterns. In order to provide a contact terminal which can electrically connect the plurality of solar cells 300 with each other and which allows a contact to the exterior or outside of the device, according to some exemplary embodiments, the transparent electrode interconnection 200 may have a plurality of interconnections passing all or some of the plurality of solar cells 300. While FIGS. 3A and 3B show the transparent electrode interconnection 200 in a “U” shape, this configuration is for illustration purposes only, and the present inventive concept is not limited to the illustrated configuration. That is, according to various exemplary embodiments of the inventive concept, the transparent electrode interconnection 200 may be formed on the transparent substrate 100 in various other patterns so as to connect the plurality of solar cells 300 to each other.

According to some particular exemplary embodiments, when interconnections in the transparent electrode interconnection 200 are arranged longitudinally and parallel to each other as shown in FIGS. 3A and 3B, ends of the interconnections at one side of the transparent electrode interconnection 200 are connected transversely so as to connect the solar cells 300 on the right side with those on the left side. In the exemplary embodiments shown in FIGS. 3A and 3B, upper ends of the interconnections in the transparent electrode interconnection 200 are connected transversely to each other.

In some exemplary embodiments, the other end of the transparent electrode interconnection 200 is separated into two regions having different polarities, that is, positive and negative electrodes, as illustrated in FIGS. 3A and 3B. In the exemplary embodiments shown in FIGS. 3A and 3B, lower ends of the interconnections in the transparent electrode interconnection 200 are separated into two groups on the left and right sides, the two groups having negative and positive polarities, respectively. Thus, electrical power can be supplied to the outside or exterior of the device by making an external contact with the lower end of the transparent electrode interconnection 200 on the left side and the upper end of the transparent electrode on the right side.

Although six parallel vertical interconnections in the transparent electrode interconnection 200 are illustrated in FIGS. 3A and 3B as passing each of the plurality of solar cells 300, according to exemplary embodiments of the inventive concept, the number of vertical interconnections may be adjusted as shown in FIGS. 4A and 4B. In particular, if more than a predetermined number of vertical interconnections pass each solar cell 300, resistance will increase, thereby causing power loss. Therefore, the number of vertical interconnections may be appropriately determined using considerations of resistance. While FIGS. 4A and 4B illustrate the number of vertical interconnections passing each solar cell 300 is reduced to 2, this configuration is for illustration purposes only. The inventive concept is not limited to this configuration.

As described above, according to the exemplary embodiments of the inventive concept, the plurality of solar cells 300 are arranged on the transparent electrode interconnection 200 overlying the transparent substrate 100. In order to maximize the spatial efficiency of arranging the plurality of solar cells 300, the solar cells 300 may be arranged parallel to each other at the smallest possible distance apart.

While FIGS. 4A and 4B illustrate the plurality of solar cells 300 as being rectangular, that configuration is for illustration purposes only. The inventive concept is not limited to that configuration, and may have other various shapes.

As described above, according to the exemplary embodiments of the inventive concept, in the solar cell module according to the present exemplary embodiments, the plurality of solar cells 300 are arranged on the transparent electrode interconnection 200 overlying the transparent substrate 100, so that they are electrically connected to each other without using a separate wire. Thus, the solar cell module according to the present exemplary embodiments provides a solar cell module which is thinner and more lightweight than other solar cell modules.

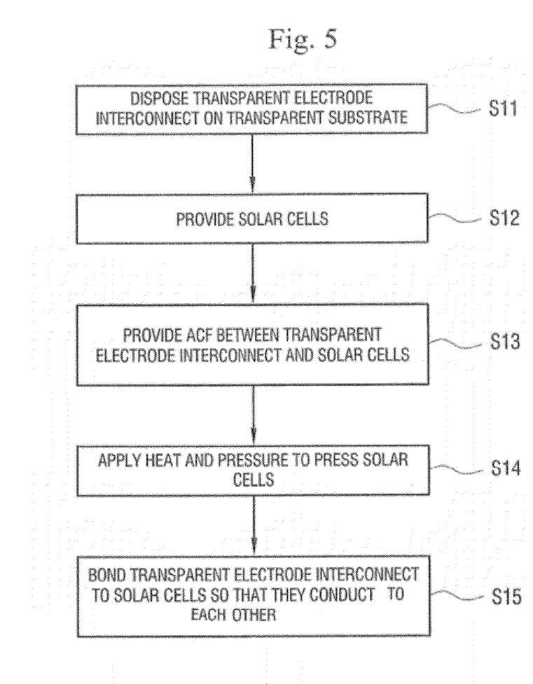

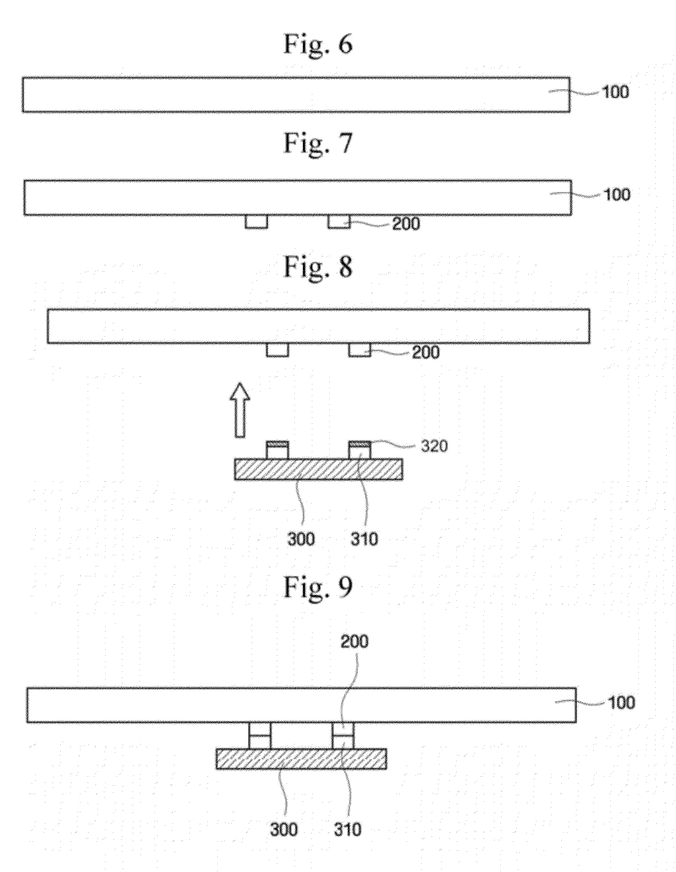

A method of manufacturing a solar cell module according to exemplary embodiments of the present inventive concept will now be described with reference to FIGS. 5 through 9. FIG. 5 is a flowchart of a method of manufacturing a solar cell module according to exemplary embodiments of the present inventive concept, and FIGS. 6 through 9 are schematic cross-sectional views sequentially illustrating steps of a method of manufacturing a solar cell module according to exemplary embodiments of the present inventive concept.

The method of manufacturing a solar cell module according to the present exemplary embodiments includes farming or disposing a transparent electrode interconnection on a transparent substrate (Step S11), providing a plurality of solar cells, each having protrusions on one surface (Step S12), disposing an anisotropic conductive film (ACF) between the transparent electrode interconnection and the protrusions (Step S13), pressing the solar cells onto the transparent electrode interconnection for thermal compression (Step S14), and bonding the protrusions to the transparent electrode interconnection using a partially melted and solidified ACF so that they conduct to each other (Step S15).

Referring to FIGS. 5 through 9, a transparent substrate 100 is provided, and a transparent electrode interconnection 200 is disposed on the transparent substrate 100 (Step S11). As described above, in some exemplary embodiments, the transparent substrate 100 may be made of for example, a transparent material such as glass, a transparent plastic film, or a transparent plastic sheet. In some exemplary embodiments, the transparent electrode interconnection 200 may be formed of for example, at least one material selected from the group consisting of ITO, IZO, CNT, nanowire, and conductive polymer that permit light to pass through the transparent electrode interconnection 200 and have excellent electrical conductivity. In particular, in some exemplary embodiments, when the solar cell module according to the present embodiment is used in flexible electronic devices, the transparent electrode interconnection 200 may be formed of, for example, highly flexible CNT, nanowire, conductive polymer, or a mixture of these materials

In some exemplary embodiments, the transparent electrode interconnection 200 overlying the transparent substrate 100 may include a plurality of interconnections passing some of the solar cells 300 in order to provide a contact terminal which can electrically connect the plurality of solar cells 300 with each other and which allows a contact to the outside or exterior of the device. According to various exemplary embodiments of the inventive concept, the transparent electrode interconnection 200 may be formed on the transparent substrate 100 in various patterns.

In some exemplary embodiments, the transparent electrode interconnection 200 may have a plurality of recesses formed therein so as to permit a flip-chip bonding to the protrusions 310 of the solar cells 300.

The plurality of solar cells 300 having the protrusions 310 formed thereon are provided (Step S12). As described above, in the plurality of solar cells 300, incident light creates an EHP. An electric field produced at a pn junction causes electrons to move to an N-type semiconductor material and holes to move to a P-type semiconductor material, thereby generating electrical current and power. Each solar cell 300 includes a semiconductor material that absorbs incident sunlight to generate electric charges and first and second electrodes disposed on a light-receiving surface of the semiconductor material.

In some exemplary embodiments, an ACF 320 is then interposed between the transparent electrode interconnection 200 and the protrusions 310 (Step S13). The solar cells 300 having protrusions 310 thereon are thermally compressed against the transparent electrode interconnection 200 to be bonded to each other (Step S14).

In some exemplary embodiments, when recesses are formed in the transparent electrode interconnection 200, the ACF 320 is mounted between the recesses and the protrusions 310. As described above, the ACF 320 may be formed by dispersing conductive particles in a thermo-setting resin. When heat and pressure are applied with the ACF interposed between the recesses and the protrusions 310, the ACF melts. After cooling, the ACF is solidified so as to bond the recesses to the protrusions 310. Since conductive particles are dispersed within the ACF 320, electrical conduction can be maintained between the recesses and protrusions 310. Referring specifically to FIG. 8, the ACF 320 may be selectively mounted on a region where the protrusions 310 are in contact with the transparent electrode interconnection 200. After one surface of the ACF is bonded to the protrusions 310, heat and pressure are applied so as to press the protrusions 310 against the transparent electrode interconnection 200 and bond them together.

Subsequently, referring specifically to FIG. 9, the thermally compressed ACF 320 transiently and partially melts due to the applied heat and pressure and resolidifies to bond the protrusions 310 to the transparent electrode interconnection 200 so that they conduct to each other (Step S15).

Thus, as described above, in some exemplary embodiments, the plurality of solar cells 300 joining with the transparent electrode interconnection 200 are physically separated from each other but are electrically connected to each other through the transparent electrode interconnection 200. Thus, this method according to the inventive concept does not require the use of wire bonding, thereby reducing the volume of the solar cell module, thereby providing an ultra-thin solar cell module.

As described above with reference to FIGS. 3A and 3B, according to some exemplary embodiments, two ends of the transparent electrode interconnection 200 act as first and second electrodes, with positive and negative polarities, that allow contact with the outside or exterior of the device. In some particular exemplary embodiments, the first and second electrodes are disposed adjacent one edge of the transparent substrate.

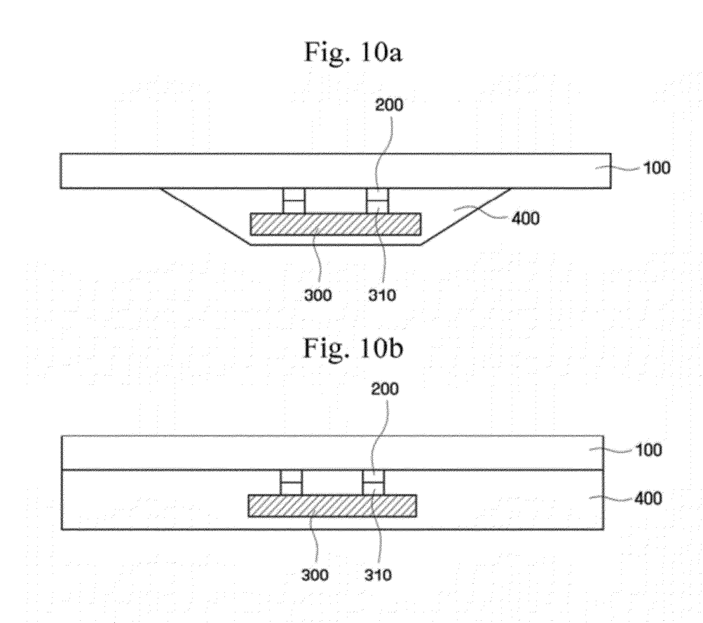

A solar cell module according to other exemplary embodiments of the present inventive concept will now be described with reference to FIGS. 10A and 10B. FIGS. 10A and 10B are schematic cross-sectional views of a solar cell module according to the other exemplary embodiments of the present inventive concept.

A difference between the embodiments of the inventive concept illustrated in FIGS. 10A and 10B and the embodiments described in detail above is that the solar cell module according to the present embodiments illustrated in FIGS. 10A and 10B further includes a transparent resin 400 encapsulating the plurality of solar cells 300. Detailed description of like elements will not be repeated.

Referring to FIGS. 10A and 10B, according to some exemplary embodiments, a portion of or the entirety of the transparent substrate 100 is coated with the transparent resin 400 so that the transparent resin 400 surrounds the plurality of solar cells 300 and the transparent electrode interconnection 200. Due to its light transmission, filling of the transparent resin 400 in a light-receiving region of the solar cell 300 does not affect the efficiency of the solar cell 300.

The transparent resin 400 protects the solar cells 300 and the transparent electrode interconnection 200 against external shock. In some solar cell modules using wire bonding as described above, applying a coat of the transparent resin 400 may increase the height of the solar cell module by the volume and height of a wire. Conversely, the solar cell module according to the present exemplary embodiments, without a wire and a PCB substrate, is configured to have the transparent electrode interconnection 200 directly on the transparent substrate 100 and the solar cells 300 so that the transparent electrode interconnection 200 conducts with the solar cells 300. Thus, an unitra-thin, lightweight solar cell module can be provided, according to the exemplary embodiments of the present inventive concept.

In some exemplary embodiments, the transparent resin 400 may be formed of any transparent material that allows the penetration of light. For example, in some exemplary embodiments, the transparent resin 400 may be underfill resin or ethylene vinyl acetate (EVA). FIG. 10A is a schematic cross-sectional view of a solar cell module using underfill resin as the transparent resin 400, and FIG. 10B is a schematic cross-sectional view of a solar cell module using EVA as the transparent resin 400. In some exemplary embodiments according to the inventive concept, in order to reduce the overall volume of the solar cell module, the transparent resin 400 may be applied selectively on a desired portion of the transparent substrate 100.

Applying the transparent resin 400 on the transparent substrate 100 may prevent an external contact to the transparent electrode interconnection 200 where electrons and holes created in the solar cell 300 move. Thus, in order to supply electrical power generated by the solar cells to the outside or exterior of the device, a via hole may be formed in the transparent resin 400 so as to provide an external contact with electrodes formed in the transparent electrode interconnection 200.

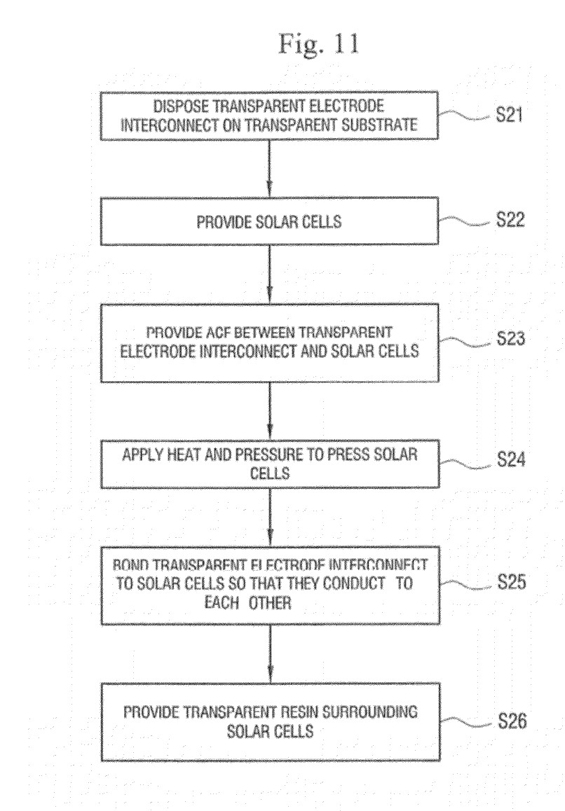

The method of manufacturing a solar cell module according to other exemplary embodiments of the present inventive concept will now be described with reference to FIG. 11. FIG. 11 is a flowchart of the method of manufacturing a solar cell module according to the other exemplary embodiments of the present inventive concept.

Referring to FIGS. 10A, 10B, and 11, the method of manufacturing a solar cell module according to the present exemplary embodiments further includes providing the transparent resin 400 encapsulating the plurality of solar cells 300 (Step S26). As described above, in some exemplary embodiments, the transparent resin 400 may be underfill resin or EVA. More specifically, in some exemplary embodiments, liquid resin is applied on a desired portion of the transparent substrate 100 and then cured so as to protect internal components such as the transparent electrode interconnection 200 and the solar cells 300 from external shock.

As described above, the manufacturing method according to the present exemplary embodiments allows a flip-chip connection without using wire bonding. The method can provide a solar cell module having a reduced thickness by forming the transparent electrode interconnect 200 on the transparent substrate 100 without a separate PCB substrate.

While the present inventive concept has been particularly shown and described with reference to exemplary embodiments thereof, it will be understood by those of ordinary skill in the art that various changes in form and details may be made therein without departing from the spirit and scope of the present inventive concept as defined by the following claims. It is therefore desired that the present embodiments be considered in all respects as illustrative and not restrictive, reference being made to the appended claims rather than the foregoing description to indicate the scope of the inventive concept.

What is claimed is:

1. A solar cell module, comprising:
a transparent substrate;
a transparent electrode interconnection disposed on the transparent substrate; and
a plurality of solar cells disposed on the transparent electrode interconnection, each solar cell having at least one protrusion formed on one surface of the solar cell, the protrusion being bonded to the transparent electrode interconnection.

2. The module of claim 1, wherein the transparent substrate comprises glass.

3. The module of claim 1, wherein the transparent electrode interconnection comprises at least one material selected from the group consisting of Indium Tin Oxide (ITO), Indium Zinc Oxide (IZO), Carbon Nanotube (CNT), nanowire, and conductive polymer.

4. The module of claim 1, wherein recesses are formed at locations on the transparent electrode interconnection in correspondence with locations of the protrusions.

5. The module of claim 1, wherein an anisotropic conductive film (ACF) is interposed between the transparent electrode interconnection and the protrusion.

6. The module of claim 1, further comprising a transparent resin surrounding the plurality of solar cells.

7. The module of claim 6, wherein the transparent resin comprises at least one of underfill resin and ethylene vinyl acetate (EVA).

8. The module of claim 1, wherein the plurality of solar cells are electrically connected by the transparent electrode interconnection.

9. The module of claim 8, wherein two ends of the transparent electrode interconnection act as first and second electrodes that allow contact with an exterior of the module, and the first and second electrodes are disposed adjacent to one edge of the transparent substrate.

10. A solar cell module, comprising:
a transparent substrate;
a transparent electrode interconnection disposed on the transparent substrate; and
a plurality of solar cells disposed on the transparent electrode interconnection, each solar cell having at least one protrusion formed on one surface of the solar cell, the protrusion being bonded to the transparent electrode interconnection,
wherein recesses are formed at locations on the transparent electrode interconnection corresponding to locations of the protrusions, the recesses mating with the protrusions.

11. The module of claim 10, wherein the transparent substrate comprises glass.

12. The module of claim 10, wherein the transparent electrode interconnection comprises at least one material selected from the group consisting of Indium Tin Oxide (ITO), Indium Zinc Oxide (IZO), Carbon Nanotube (CNT), nanowire, and conductive polymer.

13. The module of claim 10, wherein an anisotropic conductive film (ACF) is interposed between the transparent electrode interconnection and the protrusion.

14. The module of claim 10, further comprising a transparent resin surrounding the plurality of solar cells.

15. The module of claim 10, wherein the transparent resin comprises at least one of underfill resin and ethylene vinyl acetate (EVA).

16. The module of claim 1, wherein the plurality of solar cells are electrically connected by the transparent electrode interconnection.

17. The module of claim 16, wherein two ends of the transparent electrode interconnection act as first and second electrodes that allow contact with an exterior of the module, and the first and second electrodes are disposed adjacent to one edge of the transparent substrate.

18. An energy conversion module, comprising:
a transparent substrate;
a transparent electrode interconnection disposed on the transparent substrate; and
a plurality of energy conversion cells disposed on the transparent electrode interconnection, each energy conversion cell having at least one protrusion formed on one surface of the energy conversion cell, the protrusion being bonded to the transparent electrode interconnection.

19. The energy conversion module of claim 18, wherein the energy conversion cells are solar cells converting light energy into electrical energy.

20. The energy conversion module of claim 18, wherein the energy conversion module is a solar cell module.
